(19) United States
(12) Patent Application Publication
(10) Pub. No.: US 2008/0272486 A1
(43) Pub. Date: Nov. 6, 2008

(54) CHIP PACKAGE STRUCTURE

(75) Inventors: Wei-Chung Wang, Kaohsiung County (TW); Meng-Jen Wang, Pingtung City (TW); Tong-Hong Wang, Selangor D. E. (MY)

Correspondence Address: J C PATENTS, INC., 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 12/112,255

(22) Filed: Apr. 30, 2008

(30) Foreign Application Priority Data
May 4, 2007 (TW) 96116028

(51) Int. Cl. H01L 23/488

(52) U.S. Cl. 257/737; 257/E23.023

(57) ABSTRACT

A chip package structure includes a carrier, an interposer, a plurality of electrically conductive elements, a first sealant, a chip, and a second sealant. The interposer is disposed on the carrier. The electrically conductive elements electrically connect the interposer and the carrier. The first sealant seals the electrically conductive elements. A plurality of bumps of the chip is connected to the interposer. The second sealant seals the bumps. A first glass transition temperature of the first sealant is higher than a second glass transition temperature of the second sealant. Since glass transition temperatures of the first sealant and the second sealant are different, and the first glass transition temperature of the first sealant is higher than the second glass transition temperature of the second sealant, the inner stress will be lowered and the yield is promoted.

### CROSS-REFERENCE TO RELATED APPLICATION

This application claims the priority benefit of Taiwan application serial no. 96116028, filed on May 4, 2007. The entirety of the above-mentioned patent application is hereby incorporated by reference herein and made a part of this specification.

### BACKGROUND OF THE INVENTION

1. Field of the Invention

The present invention generally relates to a package, in particular, to a chip package structure.

2. Description of Related Art

A conventional package mainly includes a carrier, a chip, an interposer, and a sealant. The chip may be electrically connected to the interposer through a plurality of bumps of the chip. The interposer may be electrically connected to the carrier through a plurality of electrically conductive elements. In order to protect the bumps of the chip and the electrically conductive elements, the sealant must seal the bumps and the electrically conductive elements. However, in the process of packaging, since the carrier, the chip, and the interposer have different coefficients of thermal expansion, but use the same sealant, the carrier, the chip, and the interposer may cause inner stress due to the heat generated deformation. Therefore, the electrical connection of the conventional package may fail due to the stress, thus increasing the defect rate of the products.

### SUMMARY OF THE INVENTION

The present invention is directed to a chip package structure, which includes a carrier, an interposer, a plurality of first electrically conductive elements, a first sealant, a chip, and a second sealant. A plurality of connection pads is disposed on an upper surface of the carrier, and a plurality of ball pads is disposed on a lower surface of the carrier. The interposer is disposed on the upper surface of the carrier, and has a first surface, a second surface, and a plurality of vias. The vias electrically conduct a plurality of first contacts of the first surface and a plurality of second contacts of the second surface. The first electrically conductive elements are disposed between the carrier and the interposer, and electrically connect the interposer and the carrier. The first sealant seals the first electrically conductive elements, and has a first glass transition temperature. The chip is flip-chip bonded on the interposer. A plurality of bumps of the chip is connected to the first contacts of the interposer. The second sealant seals the bumps, and has a second glass transition temperature. The first glass transition temperature of the first sealant is higher than the second glass transition temperature of the second sealant. The effect of the present invention resides in that this package can reduce the inner stress and the yield is high since the first sealant sealing the first electrically conductive elements and the second sealant sealing the bumps have different glass transition temperatures, and the first glass transition temperature of the first sealant is higher than the second glass transition temperature of the second sealant.

The present invention provides a chip package structure, which includes a carrier, an interposer, a plurality of first electrically conductive elements, a first sealant, a chip, and a second sealant. The carrier has an upper surface and a lower surface. A plurality of connection pads is disposed on the upper surface, and a plurality of ball pads is disposed on the lower surface. The interposer is disposed on the upper surface of the carrier, and has a first surface, a second surface, and a plurality of vias. A plurality of first contacts is disposed on the first surface, and a plurality of second contacts is disposed on the second surface. The vias electrically conduct the first contacts and the second contacts. The first electrically conductive elements are disposed between the carrier and the interposer, and electrically connect the interposer and the carrier. The first sealant seats the first electrically conductive elements, and has a first glass transition temperature. The chip is flip-chip bonded on the interposer, and has a plurality of bumps. The bumps are connected to the first contacts of the interposer. The second sealant seals the bumps, and has a second glass transition temperature. The first glass transition temperature of the first sealant is higher than the second glass transition temperature of the second sealant.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is schematic cross-sectional view of a chip package structure according to a first embodiment of the present invention.

FIG. 2 is schematic cross-sectional view of another chip package structure according to a second an embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

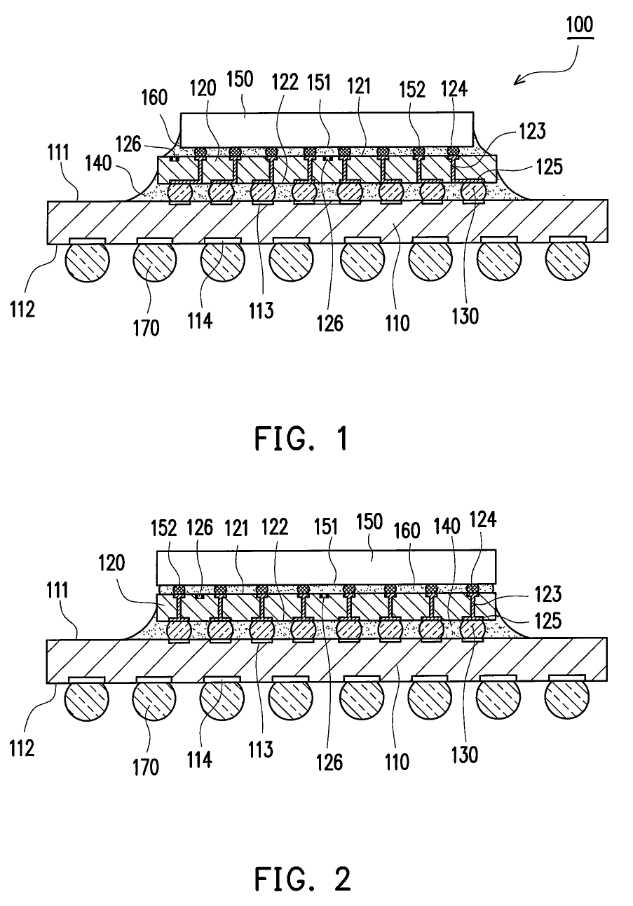

Referring to FIG. 1, in an embodiment of the present invention, a chip package structure 100 including a carrier 110, an interposer 120, a plurality of first electrically conductive elements 130, a first sealant 140, a chip 150, and a second sealant 160 is provided. The carrier 110 has an upper surface 111 and a lower surface 112. The carrier 110 may be an organic substrate or a lead frame. In this embodiment, the carrier 110 is an organic substrate. A plurality of connection pads 113 is disposed on the upper surface 111, and a plurality of ball pads 114 is disposed on the lower surface 112. The interposer 120 is disposed on the upper surface 111 of the carrier 110, and the material of the interposer 120 is silicon (Si). The interposer 120 has a first surface 121, a second surface 122, and a plurality of vias 123. A plurality of first contacts 124 is disposed on the first surface 121, and a plurality of second contacts 125 is disposed on the second surface 122. The vias 123 electrically conduct the first contacts 124 and the second contacts 125. Preferably, the interposer 120 further includes at least one integrated passive device (IPD) 126, and the IPD 126 is embedded in the first surface 121 of the interposer 120. The first electrically conductive elements 130 are disposed between the carrier 110 and the interposer 120 and electrically connect the interposer 120 and the carrier 110. The first electrically conductive elements 130 may be bumps, and electrically connect the second contacts 125 of the interposer 120 and the connection pads 113 of the carrier 110. The first sealant 140 seals the first electrically conductive elements 130, and has a first glass transition temperature (Tg₁). The first glass transition temperature of the first sealant 140 is in a range of 120 degrees centigrade to 160 degrees centigrade, and preferably, is 140 degrees centigrade. The chip 150 is flip-chip bonded on the interposer 120. In this embodiment, the chip 150 is a function chip. An active surface 151 of the chip 150 has a plurality of bumps 152, and the bumps 152 are connected to the first contacts 124 of the interposer 120, so as to form electrical connection between the chip 150 and the interposer 120, and the chip 150 is electrically connected to the carrier 110 through the interposer 120. In this embodiment, the size of the interposer 120 is larger than that of the chip 150, or, as shown in FIG. 2, the size of the chip 150 may be equal to that of the interposer 120. Referring to FIG. 1 again, the second sealant 160 seals the bumps 152, and has a second glass transition temperature (Tg₂). The first glass transition temperature of the first sealant 140 is higher than the second glass transition temperature of the second sealant 160. The second glass transition temperature of the second sealant 160 is smaller than 100 degrees centigrade, and is in a range of 50 degrees centigrade to 90 degrees centigrade, and preferably, is 70 degrees centigrade. Furthermore, the chip package structure 100 further includes a plurality of second electrically conductive elements 170, and the second electrically conductive elements 170 may be solder balls and disposed on the ball pads 114 of the carrier 110, for externally connecting a printed circuit board (not shown). The first sealant 140 sealing the first electrically conductive elements 130 and the second sealant 160 sealing the bumps 152 have different glass transition temperatures. Therefore, the effect of the present invention resides in that inner stress of the chip package structure 100 will be lowered and the yield is promoted since the first glass transition temperature of the first sealant 140 is higher than the second glass transition temperature of the second sealant 160.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip package structure, comprising:
a carrier, having an upper surface and a lower surface, wherein a plurality of connection pads is disposed on the upper surface, and a plurality of ball pads is disposed on the lower surface;
an interposer, disposed on the upper surface of the carrier, and having a first surface, a second surface, and a plurality of vias, wherein a plurality of first contacts is disposed on the first surface, a plurality of second contacts is disposed on the second surface, and the vias electrically conduct the first contacts and the second contacts;
a plurality of first electrically conductive elements, disposed between the carrier and the interposer, and electrically connecting the interposer and the carrier;
a first sealant, sealing the first electrically conductive elements, and having a first glass transition temperature;
a chip, flip-chip bonded on the interposer, comprising a plurality of bumps connected to the first contacts of the interposer; and
a second sealant, sealing the bumps, and having a second glass transition temperature, wherein the first glass transition temperature of the first sealant is higher than the second glass transition temperature of the second sealant.

2. The chip package structure according to claim 1, wherein the second glass transition temperature of the second sealant is smaller than 100 degrees centigrade.

3. The chip package structure according to claim 1, wherein the second glass transition temperature of the second sealant is in a range of 50 degrees centigrade to 90 degrees centigrade.

4. The chip package structure according to claim 3, wherein the second glass transition temperature of the second sealant is 70 degrees centigrade.

5. The chip package structure according to claim 1, wherein the first glass transition temperature of the first sealant is in a range of 120 degrees centigrade to 160 degrees centigrade.

6. The chip package structure according to claim 5, wherein the first glass transition temperature of the first sealant is 140 degrees centigrade.

7. The chip package structure according to claim 1, wherein the chip is a function chip.

8. The chip package structure according to claim 1, wherein a size of the chip is equal to that of the interposer.

9. The chip package structure according to claim 1, wherein a size of the interposer is larger than that of the chip.

10. The chip package structure according to claim 1, wherein a material of the interposer is silicon.

11. The chip package structure according to claim 1, further comprising a plurality of second electrically conductive elements disposed on the ball pads of the carrier.

12. The chip package structure according to claim 1, wherein the carrier is an organic substrate or a lead frame.

13. The chip package structure according to claim 1, wherein the interposer further comprises at least one integrated passive device (IPD).
